(19) United States
(12) Patent Application Publication
(10) Pub. No.: US 2003/0107387 A1
(43) Pub. Date: Jun. 12, 2003

(54) Multi-beam probe card

(76) Inventors: Scott Williams, Mesa, AZ (US); Merlin Dudley, Mesa, AZ (US)

Correspondence Address: David O. Caplan, Snell & Wilmer, One Arizona Center, 400 East Van Buren, Phoenix, AZ, 85004-2202, US

(21) Appl. No.: 10/017,412

(22) Filed: Dec. 6, 2001

(51) Int. Cl. G01R 31/02

(52) U.S. Cl. 324/754

(57) ABSTRACT

Methods and device for a probe card in the form of a multi-beam probe card that includes one or more beam assemblies disposed across an opening in a head plate. The probe card has a plurality of probe needles extending through the beam assemblies that provide for wide area coverage of a wafer undergoing test prior to cutting the wafer into individual chips. The multi-beam probe card may be used in a wafer test system that is configured to send test signals to the wafer and to evaluate the signal upon return.

### FIELD OF INVENTION

The present invention generally relates to probe cards that test integrated circuits on wafers and to methods of forming the probe cards. More specifically, the present invention relates to a multi-beam probe card that provides large area coverage of a wafer during test.

### BACKGROUND

In the field of semiconductor manufacturing, it is common practice to test the semiconductor chips at various stages in the manufacturing process. In particular, due to the time and expense required to package a semiconductor chip, and given the probability that a particular semiconductor chip may have a flaw, it is common practice to inspect the wafers before the wafers are cut up into individual chips. To facilitate this testing, the wafers are often designed with small conductive pads (electrodes) on the surface of the wafer. The electrodes may be used as contact points for connecting the chip circuitry to an external tester, such as a probe device. The probe device may then send electrical signals through the electrodes to circuitry on the wafer. The probe device may also receive electrical response signals from the wafer through the electrodes and the response signals can then be processed to determine whether individual chips in the wafer are functioning properly.

The probe device typically has a probe card which holds one or more probe needles. With reference to FIG. 1, the probe needles may be oriented in various configurations which are known in the art, such as a vertical orientation 100 or a cantilevered orientation 110. During testing of the wafer, the probe needles are brought into contact with the electrodes located on the wafer. This may be done by lowering the probe card, by raising the wafer, or both, and by positioning the probe card and the wafer relative to each other such that the probes contact the electrodes appropriately.

Semiconductor geometries are constantly decreasing. More and more chips can be manufactured on a single wafer thereby creating an increased demand for the parallel testing of a greater number of chips. In order to test a large number of chips in parallel, the probe device has to make simultaneous, reliable, non-destructive, low resistance contact with all of the contact areas of the chips to be tested. The simultaneous contact of the contact areas must be made by probe needles that have ends that are substantially co-planar. Typical layouts include a plurality of needles arranged closely together in a peripheral layout (e.g., a ring), wherein the needles extend out from the ring in a cantilever orientation such that the needle ends are substantially co-planar. However, these cantilever layouts are limited by the number of probe needles that can be located on the peripheral structure (i.e., the ring). Current cantilever probe card technologies are limited to testing 32 to 64 devices in parallel, depending upon the layout of the device and on how the device is built.

Accordingly, a need exists for a probe card that provides for testing, in parallel, a large number of devices on a wafer, prior to cutting up the wafer into individual chips and for a process for making such a probe card.

### SUMMARY OF THE INVENTION

A probe card, in accordance with the present invention, addresses many of the shortcomings of the prior art. In accordance with one aspect of the present invention, a multi-beam probe card is provided and comprises a head plate having an opening and one or more beam assemblies mounted to the head plate and disposed across the head plate opening. A plurality of probe needles extend through the beam assembly for contacting the integrated circuits on the wafer undergoing test. In accordance with another aspect of the present invention, the beam assembly may comprise a support beam mounted to the head plate and a probe guide mounted to the support beam where each of the probe needles extend through the probe guide. In accordance with a further aspect of the present invention, the probe card may include a plurality of beam assemblies disposed across the head plate opening. In addition, the probe guide may have a plurality of pre-drilled through holes for receiving the probe needles.

In accordance with an exemplary embodiment, a system for simultaneous testing of a plurality of devices is provided that comprises a probe card assembly, automatic test equipment, and an interface assembly for connecting the automatic test equipment to the probe card assembly. In accordance with one aspect of the present invention, the probe card assembly may comprise a substructure and a multi-beam probe card. The substructure may comprise a printed circuit board wherein the probe card is electrically connected to the substructure.

A method of manufacturing a probe card in accordance with the present invention, utilizes a process of providing a head plate having an opening, providing a probe needle having a first end and a second end, and inserting the probe needle through a beam assembly, such that the first end of the probe needle extends through the beam assembly. The beam assembly may then be mounted on the head plate, such that the beam assembly is disposed across the opening of the head plate. In accordance with another aspect of the present invention, through holes may be drilled into the probe guide for receiving a plurality of probe needles. In accordance with a further aspect of the present invention, a plurality of beam assemblies may be disposed across the opening of the head plate, such that the beam assemblies are substantially parallel to each other and provide for wide area coverage of a wafer undergoing test prior to being cut up into individual chips.

### BRIEF DESCRIPTION OF THE DRAWING

The present invention is illustrated by way of example and not limitation in the accompanying figures, in which like references indicate similar elements, and in which:

FIG. 1 illustrates various orientations of probe needles as presently known in the art;

FIG. 2a illustrates, in perspective view, an exemplary wafer test system in accordance with certain aspects of the present invention;

FIG. 2b illustrates, in perspective view, an exemplary probe card assembly, interface assembly, and wafer undergoing test in accordance with certain aspects of the present invention;

FIG. 3 illustrates, in perspective view, an exemplary probe card assembly in accordance with certain aspects of the present invention;

FIG. 4 illustrates, in top view, an exemplary probe card in accordance with certain aspects of the present invention;

FIG. 5 illustrates, in cross-section, an exemplary probe card assembly in accordance with certain aspects of the present invention;

FIG. 6, illustrates, in perspective view, various components of an exemplary probe card in accordance with certain aspects of the present invention;

FIG. 7, illustrates, in perspective view, various components of an exemplary probe card in accordance with certain aspects of the present invention; and

FIG. 8 illustrates, in cross-section, various components of an exemplary probe card in accordance with certain aspects of the present invention.

### DETAILED DESCRIPTION

The present invention overcomes the difficulties described above that are associated with testing a large number of chips on wafers during manufacturing before the wafers are cut up into individual chips. By addressing these problems, devices and methods in accordance with various aspects of the present invention provide for a multiple beam probe card configured to cover a wide area of a wafer during semiconductor testing of integrated circuits (ICs) or chips at various stages during the fabrication process of the ICs on the wafer.

In this regard, the present invention may be described in terms of functional block components and various processing steps. It should be appreciated that such functional blocks may be realized by any number of hardware and/or software components configured to perform the specified functions. Such general techniques and components that are known to those skilled in the art are not described in detail herein.

The present invention provides for a multi-beam probe card particularly suited for the simultaneous testing of multiple devices on a wafer prior to the wafer being divided into individual chips. The multi-beam probe card of the present invention is especially applicable to the testing of a large area of a wafer, and it will be readily appreciated that the present invention may be used to simultaneously test all of the devices on the wafer at one time. Stated another way, the present invention provides for a multi-beam probe card that can be used to provide for full wafer contact (i.e., all of the devices on the wafer can be electrically contacted simultaneously).

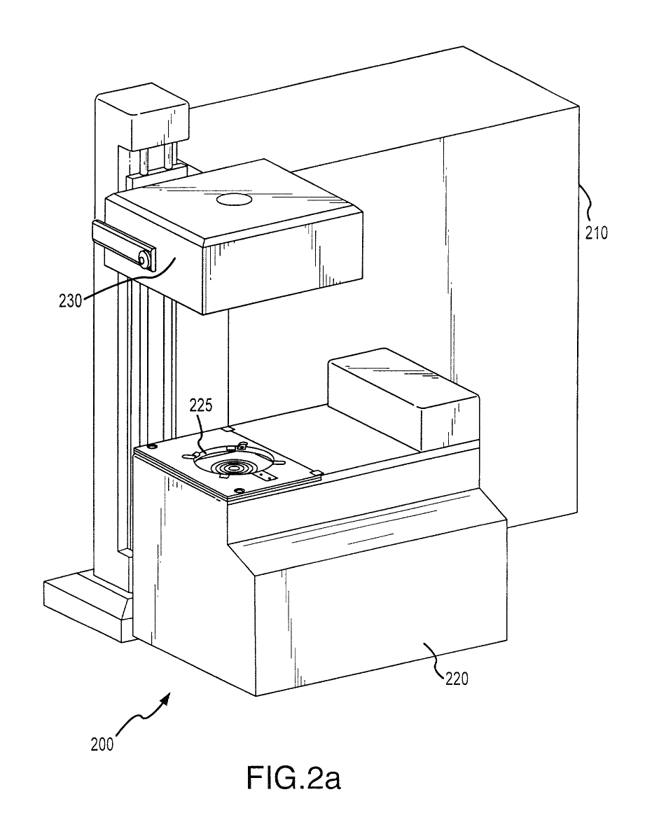

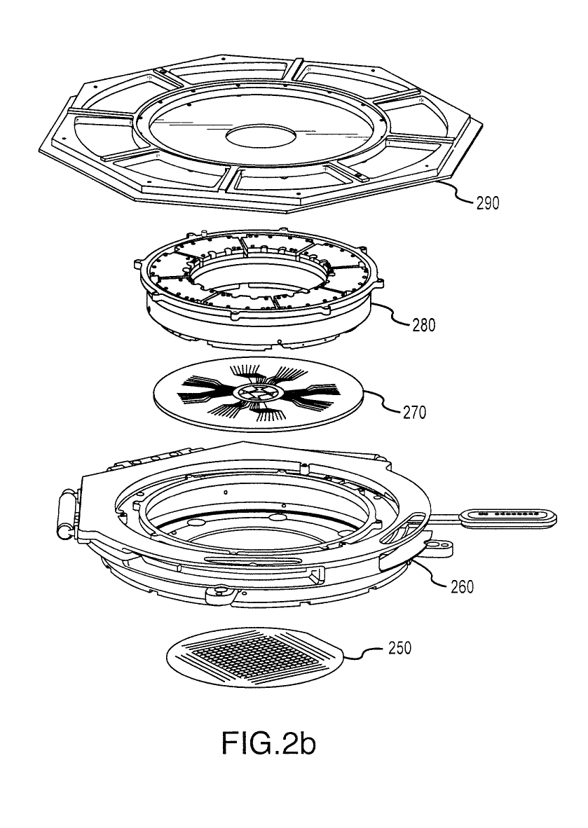

Referring to FIG. 2a, an exemplary wafer test system 200 is illustrated that is capable of utilizing a multi-beam probe card in accordance with an exemplary embodiment of the present invention. Wafer test system 200 suitably includes automatic test equipment (ATE) 210, a wafer prober 220, and an ATE test head 230. Wafer test system 200 may utilize a probe card (not illustrated in FIG. 2a), such as the multi-beam probe card of the present invention, to test a plurality of ICs on a wafer.

Automatic test equipment 210 suitably comprises equipment that is used to transmit electrical signals through ATE test head 230, interface assembly 280, and probe card assembly 270 (see FIG. 2B) to the ICs being tested. ATE 210 also suitably includes equipment for evaluating the signal upon its return. ATE 210 may include a test computer that can be configured to process signals received from the wafer through probe card assembly 270 such as a personal computer, laptop computer, computer workstation, or the like. In addition, ATE 210 may include power supply equipment and cooling equipment for the wafer test system. The ATE is well known in the art and is not described in detail herein.

Wafer prober 220 suitably comprises equipment that positions the wafer that is undergoing test by wafer test system 200. Wafer prober 220 positions the wafer such that the electrodes or pads of the devices on the wafers are aligned under the probes on the probe cards wherein the probe card can make electrical contact with the ICs located on the wafer.

With reference to FIG. 2b, a probe card assembly 270, in accordance with various aspects of the present invention, may used with an interface assembly 280, and ring assemblies 260 and 290 to contact and test various ICs on wafer 250, while wafer 250 is still in the manufacturing stage and has not been cut up into individual chips. It will be appreciated, as explained in further detail below, that a multi-beam probe card assembly 270 in accordance with the present invention can be used to simultaneously test a large number of ICs in parallel.

Interface assembly 280 suitably comprises a well-known interface structure that is configured to connect probe card assembly 270 and ATE 210 such that computer signals may pass between the probe card assembly and ATE 210. Interface assembly 280 is configured to maintain the integrity of the electrical signal between ATE 210 and probe card assembly 270.

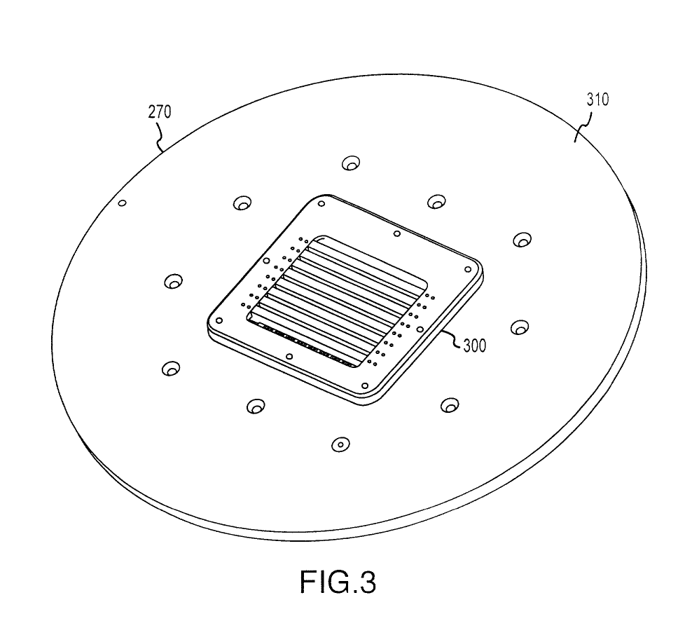

Referring now to FIG. 3, probe card assembly 270 suitably comprises a probe card 300 and a sub-structure 310. Sub-structure 310 is any suitable structure that provides a substructure for mounting the probe card. In one embodiment, sub-structure 310 may comprise a printed circuit board (PCB). Sub-structure 310 suitably provides a structure wherein the probe needles of the probe card may be in electrical contact with the ATE.

Ring assemblies 260 and 290 are used to hold probe card assembly 270 and interface assembly 280 in place and to provide for attachment to ATE head 230. Such ring assemblies and attachment to ATE head 230 are well known in the art and are not described in detail herein.

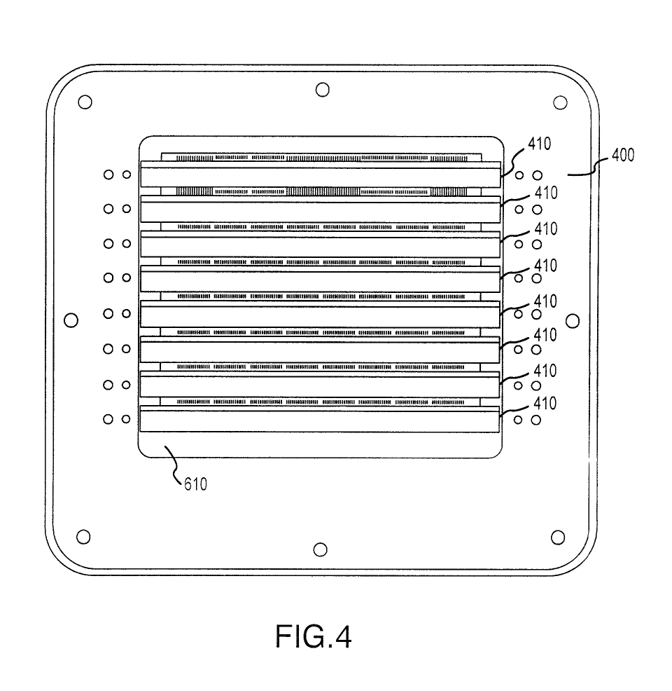

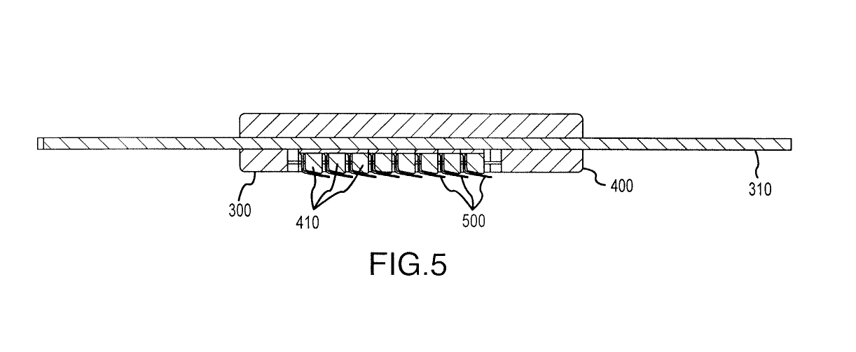

With reference to FIGS. 4 and 5, probe card 300 suitably comprises a head plate 400, one or more beam assemblies 410 mounted to the head plate, and a plurality of probe needles 500 extending through the beam assemblies. Probe needles 500 are positioned such that they can establish electrical contact with a series of metalized pads or electrodes that are located on the wafer undergoing test.

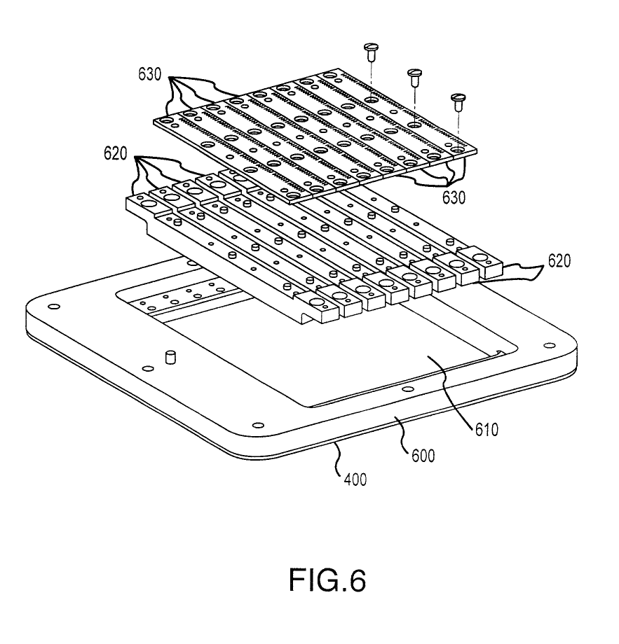

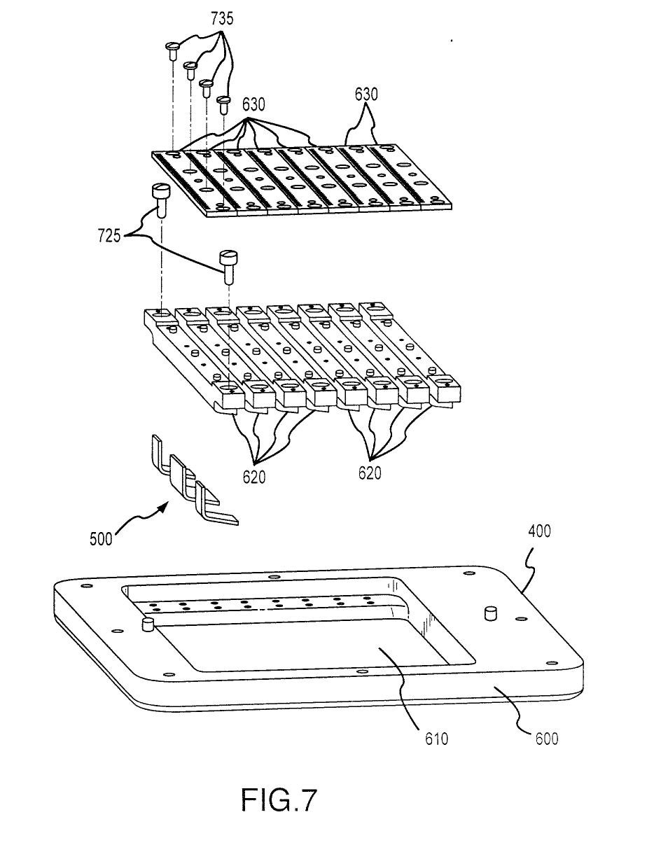

Referring now to FIGS. 6 and 7, head plate 400 suitably comprises a metal plate 600 having an opening 610. In accordance with one aspect of the present invention, head plate 400 may have an opening that is rectangular shaped. It will be appreciated, however, that head plate 400 may have an opening of various other shapes, such as circular, oval, elliptical, or a variety of other shapes that allow one or more beam assemblies to be disposed across the opening and provide wide area coverage of the wafer undergoing test. In the present embodiment, head plate 400 may comprise a metallic material such as stainless steel or aluminum. In alternate embodiments, head plate 400 may comprise a different material such as ceramic, plastic, or any other suitable material that can provide support for beam assemblies 410.

In accordance with one embodiment of the present invention, beam assembly 410 comprises a support beam 620 and a probe guide 630. Support beam 620 is mounted to head plate 400 using suitable mounting hardware 725 such as bolts, screws, or any other suitable connection hardware. Similarly, probe guide 630 is mounted to support beam 620 using suitable mounting hardware 735 such as bolts, screws, or any other suitable connection hardware. Support beam 620 and probe guide 630 may be of various lengths depending upon the application. For example, support beam 620 and probe guide 630 may be approximately 8 inches long to provide for full wafer contact. However, it will be appreciated that support beam 620 and probe guide 630 (along with head plate 400) may have a length that is shorter or longer than 8 inches depending upon the desired coverage of the probe card. Support beam 620 and probe guide 630 are made of any suitable material that can be used to provide support for probe needles 500. In the present embodiment, support beam 620 may be made of a metallic material, such as stainless steel, and probe guide may be made of any insulated material, such as a plastic or ceramic material and the like. For example, probe guide 630 may be made of an insulated material such as Vespel® from DuPont. Alternatively, support beam 620 may be made of a different metallic, ceramic, or plastic material, or any other suitable material that provides support for the beam assembly. In addition, in alternative embodiments of the present invention, beam assembly 410 may comprise other beam-like structures that provide support for probe needles 500, and optionally provide guidance for the probe needles so that the probe needles are properly positioned to establish electrical contact with the electrodes that are located on the wafer undergoing test.

As illustrated in FIG. 4, a plurality of beam assemblies 410 may be used to provide for large area coverage of a wafer. The beam assemblies may be disposed across the opening of head plate 400 such that the beam assemblies are substantially parallel and the wafer area covered by the probe needles of the beam assemblies is maximized. However, the beam assemblies may be disposed in other orientations that are non-parallel depending upon the coverage requirements of the application. The spacing between beam assemblies can vary depending upon the desired requirements needed for testing wafers. For example, the spacing between beam assemblies in one embodiment may be 0.2 inches, and in another embodiment, the spacing may be 0.5 inches. It will be readily appreciated that these are just examples of exemplary beam assembly spacings, and that the present invention is not limited to these spacings.

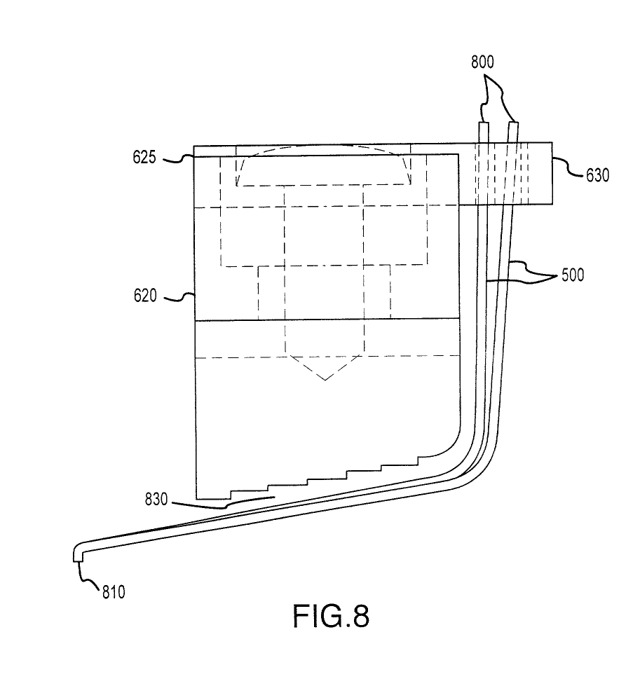

With momentary reference to FIG. 8, in accordance with another aspect of the present invention, probe needle 500 extends through probe guide 630 such that a first end 800 of the probe needle extends through the beam assembly for contacting sub-structure 310 and a second end 810 of the probe needle extends through the beam assembly for contacting the wafer undergoing test. In one embodiment of the present invention, probe needle 500 comprises cantilever probe needles as illustrated in FIG. 8. Alternatively, in other embodiments of the present invention, probe needle 500 may comprise probe needles with a different orientation such as vertical, diagonal or any combination of probe needles with various orientations. The length and number of probe needles may vary depending upon the desired electrical performance and upon the desired area of wafer coverage. For example, the number of probe needles per beam assembly may range from 800-2500 with a pitch of approximately 100 microns between probe needles. It will be readily appreciated, that these ranges are for exemplary purposes only, and the number, length, and pitch of the probe needles may vary and be smaller or larger than these ranges.

The following example illustrates a process, in accordance with one embodiment of the present invention, for manufacturing a multi-beam probe card such as the probe card depicted in FIGS. 3-8. The process may start by providing a head plate having an opening. In accordance with one embodiment of the present invention, the head plate comprises a metal plate. As discussed above, at least a portion of the metal plate has an opening that may be in the shape of a rectangle, circle, oval, or any other shape opening that permits access to wafers located in the vicinity of the opening. The opening may be located in the center of the head plate. Alternatively, the opening may be located such that the head plate is open ended, for example, in the shape of a horse shoe.

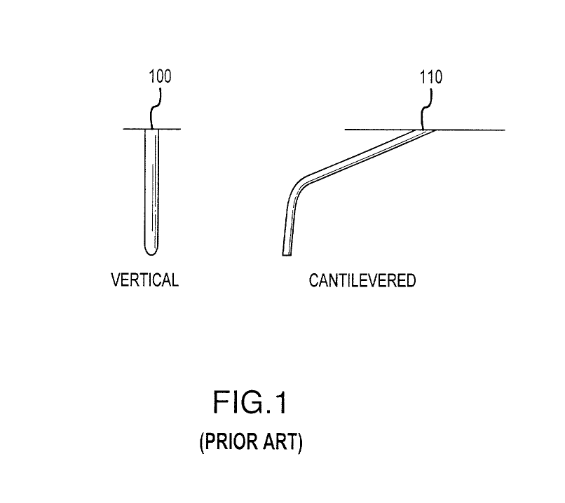

A probe needle is provided that has a first end and a second end. In accordance with one aspect of the present invention, the probe needle may be in the shape of a cantilever probe needle, such as probe needle 110 illustrated in FIG. 1. However, other probe needle shapes may be used that allow for a wide area coverage of the wafer undergoing test.

In accordance with another aspect of the present invention, epoxy may be used to attach probe needles 500 to a support beam, such as the support beam 620 illustrated in FIG. 6. For example, with reference to FIG. 8 epoxy may be used to suitably attach probe needles 500 to support beam 620, such as in an epoxy area 830. Any suitable epoxy material may be used such as a low temperature (i.e., less than or equal to 80 degrees C.) white epoxy made from a Dexter Hysol 1C and Hysol 0151 mixture.

The probe needle is inserted through a probe guide, such as probe guide 630 depicted in FIG. 6. Probe guide 630 may be pre-drilled with holes that are suitable for receiving one end of the probe needle. The position of the holes may be calculated in order to maximize the coverage of the probe needles that are placed in the drilled holes. In addition, the position of the probe guide holes may be calculated to provide for proper positioning of the probe needles such that the probe needles establish electrical contact with the electrodes of the wafer undergoing test. The drilling of the holes in the probe guide may take place at approximately the same time, or at any time prior to, inserting the probe needle through the probe guide. The process of inserting the probe needles into the probe guide may be repeated for a plurality of probe needles. The probe needles may be sanded into planarity, such that the end of each probe needle that contacts the wafer is even with the corresponding ends of the other probe needles. In accordance with a further aspect of the present invention, the ends of the probe needles may be sanded such that they are cut flush to the probe guide. It will be readily appreciated that this will result in shorter probe needle lengths which allows for more efficient probing of the wafer undergoing test.

In accordance with another aspect of the present invention, probe guide 630 may be suitably mounted to a top surface 625 of support beam 620. In this manner, a beam assembly is formed, such as beam assembly 410 illustrated in FIG. 5. The probe guide may be mounted with any suitable hardware, such as bolts, screws, or the like. It will be readily appreciated that the various steps of sanding, epoxy, and of attaching the support beam and the probe guide may take place in any order.

In accordance with a further aspect of the present invention, beam assembly 410 is suitably mounted on the head plate such that the beam assembly is disposed across the opening of the head plate. For example, with momentary reference to FIGS. 4 and 6, beam assembly 410 is disposed across opening 610 of head plate 400.

This process may be repeated for a plurality of beam assemblies such that wide area coverage of a wafer is possible and a large number of devices on the wafer can be tested simultaneously.

With reference to FIGS. 2a and 2b, in operation, wafers 250 are loaded onto surface 225 of wafer prober 220 for testing. Wafer 250 includes one or more ICs which are in various stages of fabrication. Next, ATE test head 230 containing probe card assembly 270 is lowered such that test head 230 is proximate to wafer 250. Alternatively, wafer prober 220 can be raised such that wafer 250 is proximate to test head 230. In this manner, each of the probe needles 500 (see FIG. 8) of the probe card assembly contacts the electrodes on the devices formed on wafer 250. The probe needles contact the electrodes utilizing the second end 810 of each of the probe needles. Wafer system 200 suitably positions probe card assembly 270 such that ends 810 of probe needles 500 are aligned to contact wafer 250 at the appropriate electrodes located on the devices of wafer 250. As is well known in the art, the first end 800 of each of the probe needle may contact interface assembly 280 and thus provide connectivity from the devices of wafer 250 to ATE 210 such that test signals can be sent to the wafer and the resulting signals from the wafer can be evaluated by ATE 210. Once contact is established between probe card assembly 270 and wafer 250, test signals may be sent to wafer 250 and the resulting signals may be received by assembly 270. The contact between probe card assembly 270 and wafer 250 is preferably solderless, thus reducing the amount of labor needed to test the wafer. That is, pressure contact, and not solder, may be used to provide the contact between the probe card and the wafer undergoing test. However, in alternative embodiments, solder or other similar processes may be used to -provide the contact between the probe card and the wafer.

Although the invention has been described herein in conjunction with the appended drawings, those skilled in the art will appreciate that the scope of the invention is not so limited. Modifications in the selection, design, and arrangement of the various components and steps discussed herein may be made without departing from the scope of the invention as set forth in the appended claims.

What is claimed is:

1. A probe card for testing an integrated circuit, the probe card comprising:
a head plate having an opening;
a beam assembly mounted to the head plate and disposed across the opening of the head plate; and
a plurality of probe needles extending through the beam assembly, wherein each probe needle has a first end extending through the beam assembly and a second end for contacting the integrated circuit.

2. The probe card of claim 1, wherein:
the beam assembly comprises:
a support beam mounted to the head plate; and
a probe guide mounted to the support beam; and
the first end of each probe needle extends through the probe guide.

3. The probe card of claim 2, wherein the support beam comprises a steel beam.

4. The probe card of claim 2, wherein the probe guide has a plurality of pre-drilled through-holes for receiving the first end of each probe needle.

5. The probe card of claim 1, wherein the probe needles comprise cantilever probe needles.

6. The probe card of claim 1, wherein the beam assembly has a probe needle pitch of less than approximately 100 microns.

7. The probe card of claim 1 further comprising a plurality of beam assemblies mounted to the head plate and disposed across the opening of the head plate, wherein each of the plurality of beam assemblies are substantially parallel.

8. The probe card of claim 7, wherein the plurality of probe needles are disposed in a high density array and wherein each probe needle comprises a cantilever mounted pin.

9. The probe card of claim 8, wherein each beam assembly has approximately 800-2500 probe needles.

10. A probe card assembly for providing temporary electrical connections to an integrated circuit, the probe card assembly comprising:
a sub-structure; and
a probe card comprising:
a head plate mounted to the sub-structure, wherein the head plate has an opening;
a beam assembly mounted to the head plate and disposed across the opening of the head plate; and
a plurality of probe needles extending through the beam assembly.

11. The probe card assembly of claim 10, wherein:
the beam assembly comprises:
a support beam mounted to the head plate; and
a probe guide mounted to the support beam; and
each of the probe needles extend through the probe guide.

12. The probe card assembly of claim 10, wherein the sub-structure is a printed circuit board.

13. The probe card assembly of claim 12, wherein each probe needle has a first end and a second end, wherein the first end extends through the beam assembly for contacting the printed circuit board and the second end contacts the integrated circuit.

14. The probe card assembly of claim 13, wherein the second end forms a solderless contact with the integrated circuit.

15. A system for simultaneous testing of a plurality of devices, the system comprising:
a probe card assembly comprising:
a sub-structure;
a head plate mounted to the sub-structure, wherein the head plate has an opening;
a plurality of beam assemblies mounted to the head plate and disposed across the opening of the head plate, each beam assembly comprising:
a support beam; and
a probe guide mounted to the support beam; and
a plurality of cantilever probe needles extending through the probe guide;
an automatic test equipment for receiving and analyzing electrical signals from the probe card assembly; and
an interface assembly for connecting the automatic test equipment to the probe card assembly.

16. A method of manufacturing a probe card comprising the steps of:
(a) providing a head plate having an opening;
(b) providing a probe needle having a first end and a second end;
(c) inserting the probe needle through a beam assembly, such that the first end of the probe needle extends through the beam assembly; and
(d) mounting the beam assembly on the head plate such that the beam assembly is disposed across the opening of the head plate.

17. The method of claim 16, wherein the step of inserting comprises inserting the probe needle through a probe guide, such that the first end of the probe needle extends through the probe guide; and further comprising the step of mounting the probe guide to a support beam, such that the beam assembly is formed.

18. The method of claim 17, further comprising the step of drilling a through-hole into the probe guide, wherein the through-hole is for receiving the first end of the probe needle.

19. The method of claim 16, wherein the probe needle comprises a cantilever probe needle.

20. The method of claim 16, further comprising repeating the mounting step for a plurality of beam assemblies, wherein the beam assemblies are configured substantially parallel to each other.
